(19) United States
(12) Patent Application Publication
(10) Pub. No.: US 2024/0282860 A1
(43) Pub. Date: Aug. 22, 2024

(54) NONLINEAR CHANNEL

(71) Applicant: INTERNATIONAL BUSINESS MACHINES CORPORATION, ARMONK, NY (US)

(72) Inventors: Ruilong Xie, Niskayuna, NY (US); Julien Frougier, Albany, NY (US); Susan Ng Emans, Albany, NY (US); Andrew M. Greene, Slingerlands, NY (US)

(21) Appl. No.: 18/171,528

(22) Filed: Feb. 20, 2023

(51) Int. Cl. H01L 29/78; H01L 21/308; H01L 29/66

(52) U.S. Cl. CPC H01L 29/7853; H01L 21/3086; H01L 29/66795; H01L 21/3065

(57) ABSTRACT

A finFET that includes a nonlinear channel is presented. The nonlinear channel includes one or more arced, curved, segmented, or the like, sidewall(s) that define a channel width and a channel length. The nonlinear channel provides a relatively increased channel length compared to a linear fin that is orientated orthogonal to the gate width. As such, channel length of the nonlinear channel may be relatively increased within the confines of the gate. In other words, short channel effects may be limited due to a reduced electric field along the nonlinear channel due to the relatively increased channel or fin length within the footprint of the gate.

### BACKGROUND

The present disclosure relates to fabrication methods and resulting structures for semiconductor devices. More specifically, the present disclosure relates to fabrication methods and resulting structures for integrated circuit (IC) devices, such as wafers, dies, processors, etc., that include a transistor, such as a finFET, that has a nonlinear channel.

Semiconductor devices and IC devices have become ubiquitous within many products, particularly as they continue to decrease in cost and size. There is a continued desire to reduce the size of structural features and/or to provide a greater amount of structural features for a given device size. Miniaturization, in general, allows for increased performance at lower power levels and lower cost. Present technology is at or approaching atomic level scaling of certain micro-devices such as logic gates, field-effect transistors (FETs), capacitors, and the like.

For example, when a width of a fin of a finFET scales down or reaches 5 nanometers (nm) (around the 3 nm node), a contacted poly pitch (CPP) reaches a CPP limit of roughly 45 nm with a metal pitch of 22 nm. CPP is the distance separating respective centers of adjacent gate contacts. The CPP limit may be caused by a desire to minimize or eliminate short channel effects, caused by a desire to minimize parasitic capacitance increases caused by smaller gate spacer width, and/or caused by shrinking space for source and/or drain contacts.

To achieve expected finFET functionality, the gate electric field should typically control the channel and the drain electric field should have a lesser effect on the channel. Otherwise, the finFET will show a set of unwanted effects called short channel effects. One way to reduce the propensity of short channel effects is to increase the gate length (Lg).

### SUMMARY

In an embodiment of the present disclosure, a finFET is presented. The finFET includes a nonlinear channel under a gate. The nonlinear channel includes a first nonlinear sidewall. The first nonlinear sidewall is nonlinear (i.e., not straight), the nonlinear sidewall results in a relatively increased channel length within the confines of a footprint of the gate. This increased channel length is larger relative to an associated linear fin that is straight across the gate length. In other words, short channel effects may be limited due to a reduced electric field along the nonlinear channel due to the relatively increased channel length.

In an example, the nonlinear channel may further include a second nonlinear sidewall that opposes the first nonlinear sidewall. In an example, the first nonlinear sidewall is a first curved nonlinear sidewall and/or the second nonlinear sidewall is a second curved nonlinear sidewall. In an example, the first curved nonlinear sidewall and the second curved nonlinear sidewall are parallel. In an example, the first curved nonlinear sidewall and the second curved nonlinear sidewall share a same central axis of curvature.

In an example, the finFET further includes a source in physical contact with a first end surface of the nonlinear channel and a drain in physical contact with an opposing second end surface of the nonlinear channel. In an example, the finFET further includes a gate spacer around the gate. In an example, the channel length of the nonlinear channel is greater than the gate length of the gate.

In an example, the first nonlinear channel includes a first nonlinear sidewall and a second nonlinear sidewall that opposes the first nonlinear sidewall. In an example, the first nonlinear sidewall is a first curved sidewall and the second nonlinear sidewall is a second curved sidewall.

In an example, the second nonlinear channel includes a third nonlinear sidewall and a fourth nonlinear sidewall that opposes the first nonlinear sidewall. In an example, the third nonlinear sidewall is a third curved sidewall and the fourth nonlinear sidewall is a fourth curved sidewall.

In an example, the first curved sidewall and the second curved sidewall are parallel and the third curved sidewall and the fourth curved sidewall are parallel. In an example, the first curved sidewall, the second curved sidewall, the third curved sidewall, and the fourth curved sidewall share a same central axis of curvature.

In an example, the finFET further includes a gate spacer around the gate. In an example, the channel length of the first nonlinear channel is greater than a gate length of the gate. In another example, the channel length of the second nonlinear channel is greater than the gate length.

In another embodiment of the disclosure, a finFET fabrication method is presented. The method includes forming a nonlinear fin over a semiconductor substrate, forming a sacrificial gate over the nonlinear fin, forming gate spacers upon respective sidewalls of the sacrificial gate, forming a source in physical contact with a first end surface of the nonlinear fin, forming a drain in physical contact with a second end surface of the nonlinear fin, removing the sacrificial gate between the gate spacers, and forming a replacement gate between the gate spacers. The nonlinear fin is a nonlinear channel for the finFET and a channel length of the nonlinear channel is greater than the replacement gate length.

This nonlinear channel length is relatively greater compared to a linear fin. As such, the nonlinear channel length may be relatively increased within the confines of the footprint (e.g., gate length (Lg) by gate width) of the replacement gate. In other words, short channel effects may be limited due to a reduced electric field along the nonlinear channel due to the relatively increased channel or fin length within the footprint of the replacement gate.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-sectional view and a top-down view of a semiconductor device that includes a nonlinear channel, according to embodiments of the disclosure.

FIG. 2 through FIG. 9 depicts cross-sectional views of a semiconductor device that includes a nonlinear channel at various fabrication stages of a fabrication process, according to embodiments of the disclosure.

FIG. 10 depicts a method of fabricating a semiconductor device that includes a nonlinear channel, according to embodiments of the disclosure.

FIG. 11 through FIG. 13 depicts cross-sectional views of a semiconductor device that includes a nonlinear channel at various fabrication stages of a fabrication process, according to embodiments of the disclosure.

FIG. 14 depicts a method of fabricating a semiconductor device that includes a nonlinear channel, according to embodiments of the disclosure.

### DETAILED DESCRIPTION

To reduce the propensity of short channel effects, the gate length (Lg) has typically been increased. However, as the CPP scales down, there's less space to increase dimensions of the gate.

Aspects of the disclosure may limit short channel effects within finFETs and may allow for further scaling of finFETs. More specifically, a finFET that includes a nonlinear fin is provided. The nonlinear fin has a larger channel length relative to an associated linear fin (e.g., a conventional FinFET with a perpendicularly straight fin or channel across the gate length (Lg)). The channel length of the nonlinear fin may be obtained without increasing geometries of the other finFET features, such as the gate length (Lg), gate spacer width, or the like. Therefore, the geometries of finFETs that include nonlinear fins may further scale while obtaining the benefit of the relative increased channel length of the nonlinear fins. Increasing the channel length reduces the short channel effect because electrical field is reduced along the longer channel length.

The flowcharts and cross-sectional diagrams in the drawings illustrate methods of fabricating IC devices that include a nonlinear fin, according to various embodiments of the disclosure. In some alternative implementations, the fabrication steps may occur in a different order that that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and/or IC fabrication may or may not be described in detail herein. Moreover, the various tasks and process steps described herein can be incorporated into a more comprehensive procedure or process having additional steps or functionality not described in detail herein. Various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a semiconductor device, such as a micro-chip, that will be packaged into an IC fall into four general categories, namely, material deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Materials of both conductors (e.g., poly-silicon, aluminum, copper, etc.) and insulators (e.g., various forms of silicon dioxide, silicon nitride, etc.) are used to connect and isolate other wiring or device components. Semiconductor lithography is the formation of three-dimensional relief images or patterns in the underlying material(s) for subsequent transfer of the pattern to the material(s). In semiconductor lithography, the patterns are formed by a light sensitive polymer called a photo-resist.

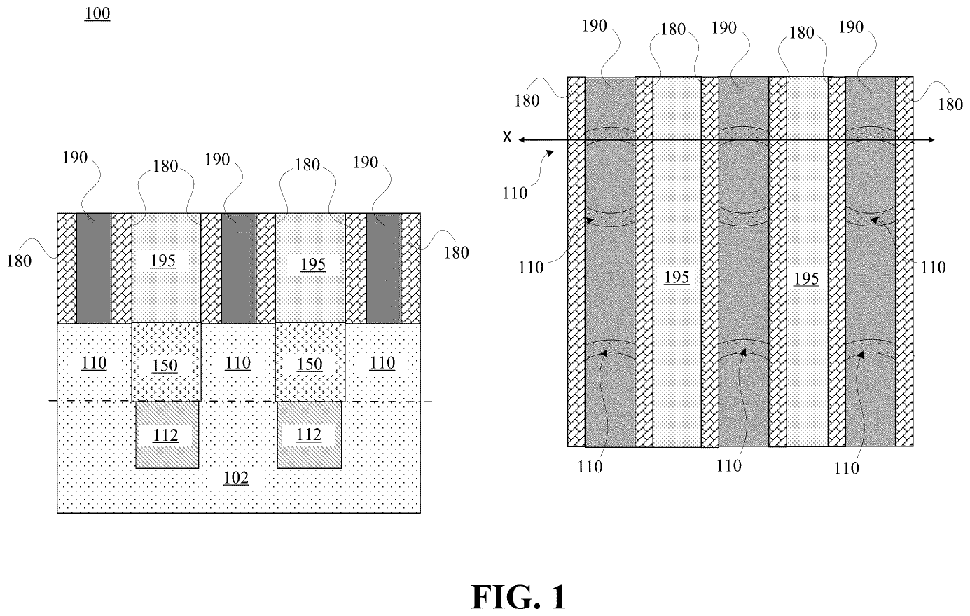

Referring now to the drawings in which like numerals represent the same or similar elements and initially to FIG. 1 which depicts a cross-sectional view and top-down view of a semiconductor device 100 that includes a nonlinear channel 110, according to embodiments of the disclosure. The term “nonlinear channel” is defined herein to be a channel that includes opposing sidewalls (i.e., oppositely facing sidewalls) that define a nonlinear fin length that are not parallel with the X-cross-section, as depicted, which is generally orthogonal to an associated gate width.

The term “nonlinear” is defined herein to be not straight. As such, a nonlinear fin length would include at least one not straight sidewall amongst the opposing sidewalls that define the fin length. For example, a nonlinear fin length may include include one or more curved sidewalls that define the fin length. For example, a nonlinear channel may include one or more curved sidewalls that define the fin length, a nonlinear channel may include a first set of straight segmented sidewalls and a second set of straight segmented sidewalls angled relatively to the first set of segmented signed walls (e.g., a V shaped nonlinear channel, or the like).

Semiconductor device 100 may further include semiconductor substrate 102, one or more isolation regions 112, one or more source/drain 150, one or more replacement gate 190, one or more gate spacer 180, and one or more interlayer dielectric 195.

Nonlinear channel 110 may include arced, curved, segmented, or the like, sidewall(s) that define the fin or channel width 181 and/or the fin or channel length 185. Specifically, as depicted, nonlinear channel 110 may include arced or curved sidewalls that define the channel or fin length 185. The nonlinear channel 110 generally has a longer channel or fin length 185 compared to a typical linear fin (i.e., a fin that is parallel to the X-plane, as depicted). As such, the channel or fin length 185 of the nonlinear channel 110 may be relatively increased within the confines of a footprint or the replacement gate structure (e.g., the gate length (Lg) x the gate width of the replacement gate 190). In other words, the fin or channel length 185 of the nonlinear channel 110 may be relatively increased without also increasing the gate length (Lg) 183 of the replacement gate 190. Though shown with arced or curved sidewalls, nonlinear channel 110 may include V-shaped sidewalls, hexagonal sidewalls, or other segmented sidewalls the like that define the fin length.

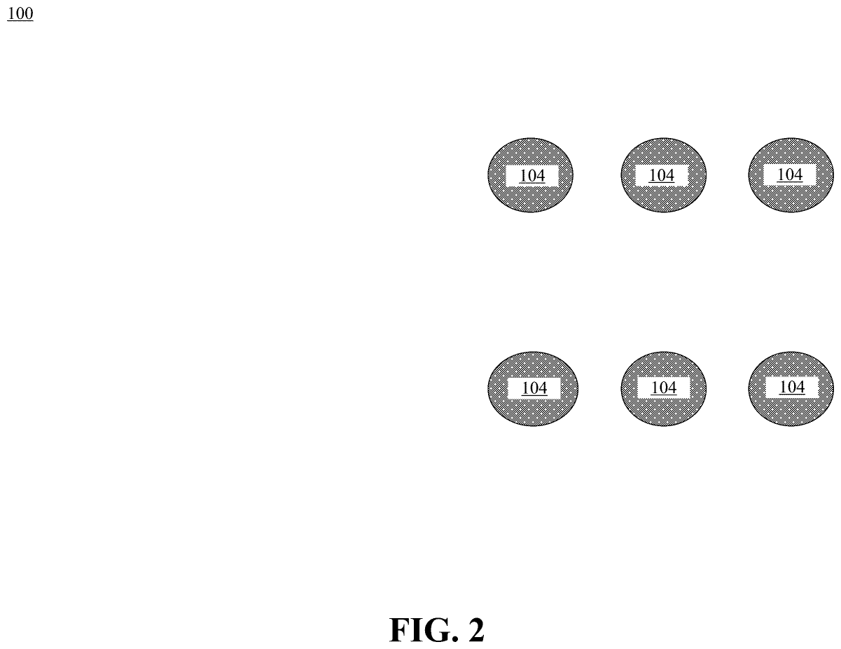

FIG. 2 depicts a top-down view of semiconductor device 100 that is to include nonlinear channel 110 at another stage of the fabrication process, according to embodiments of the disclosure. At the present fabrication stage, a hard mask (not shown) and one or more fin mandrels 104 are formed upon over semiconductor substrate 102.

Semiconductor substrate 102 includes a semiconductor material including, but not limited to, silicon (Si), silicon germanium (SiGe), silicon carbide (SiC), Si:C (carbon doped silicon), silicon germanium carbide (SiGeC), carbon doped silicon germanium (SiGe:C), III-V, II-V compound semiconductor or other like semiconductor. In addition, multiple layers of the semiconductor materials can be used as the semiconductor material of the substrate. The semiconductor substrate 102 can be a bulk substrate, as depicted in the present example, or a semiconductor-on-insulator substrate such as, but not limited to, a silicon-on-insulator (SOI), silicon-germanium-on-insulator (SGOI) or III-V-on-insulator substrate including a buried insulating layer, such as, for example, a buried oxide or nitride layer.

A hardmask (not shown) including, for example, a nitride material, such as, but not necessarily limited to, silicon nitride (SiN) or titanium nitride (TiN), may be formed on the substrate 102. The hardmask can be deposited using deposition techniques including, but not necessarily limited to, chemical vapor deposition (CVD), plasma enhanced CVD (PECVD), radio-frequency CVD (RFCVD), physical vapor deposition (PVD), atomic layer deposition (ALD), molecular layer deposition (MLD), molecular beam deposition (MBD), pulsed laser deposition (PLD), liquid source misted chemical deposition (LSMCD), and/or sputtering. In some embodiments, a planarization process, such as, chemical mechanical planarization (CMP) can be used to remove excess hardmask material. A height of the hardmask can be in the range of, but is not necessarily limited to, 20 nm to 100 nm.

The one or more fin mandrels 104 comprise, but are not necessarily limited to, amorphous silicon (a-Si), amorphous carbon, polycrystalline silicon, polycrystalline silicon germanium, amorphous silicon germanium, polycrystalline germanium, and/or amorphous germanium, are formed on hardmask and spaced apart from each other. The mandrel 104 formation can be done by various patterning techniques, including, but not necessarily limited to, lithography patterning followed by directional etching and/or a sidewall image transfer (SIT) process, for example. In some embodiments, the process includes using lithography followed by directional etching (e.g., reactive ion etch (ME)) to form the one or more fin mandrels 104.

In an example, fin mandrel 104 may be a circular column and have a circular sidewall that has one center axis located into and out of the page. In this example, nonlinear channels 110 that are fabricated associated therewith may also have circular sidewalls that define the fin width. The sidewalls associated with the nonlinear channels may have the same center axis of the fin mandrel. In another example, as depicted, each mandrel 104 may be an oblong oval column and have an arced sidewall that has two focal axes that are located into and out of the page. In this example, nonlinear channels 110 that are fabricated associated therewith may also have oval arced sidewalls that define the fin length. In another example, each mandrel 104 may be diamond column and have segmented sidewalls. In this example, nonlinear channels 110 that are fabricated associated therewith may also have V-shaped segmented sidewalls that define the fin width. In another example, each mandrel 104 may be diamond column and have segmented sidewalls. In this example, nonlinear channels 110 that are fabricated associated therewith may also have V-shaped segmented sidewalls that define the fin width. In another example, each mandrel 104 may be polygonal column (e.g., hexagonal column, etc.) that has one central bisector axis, into and out of the page, and have associated segmented sidewalls. In this example, nonlinear channels 110 that are fabricated associated therewith may also have polygonal segmented sidewalls that define the fin width.

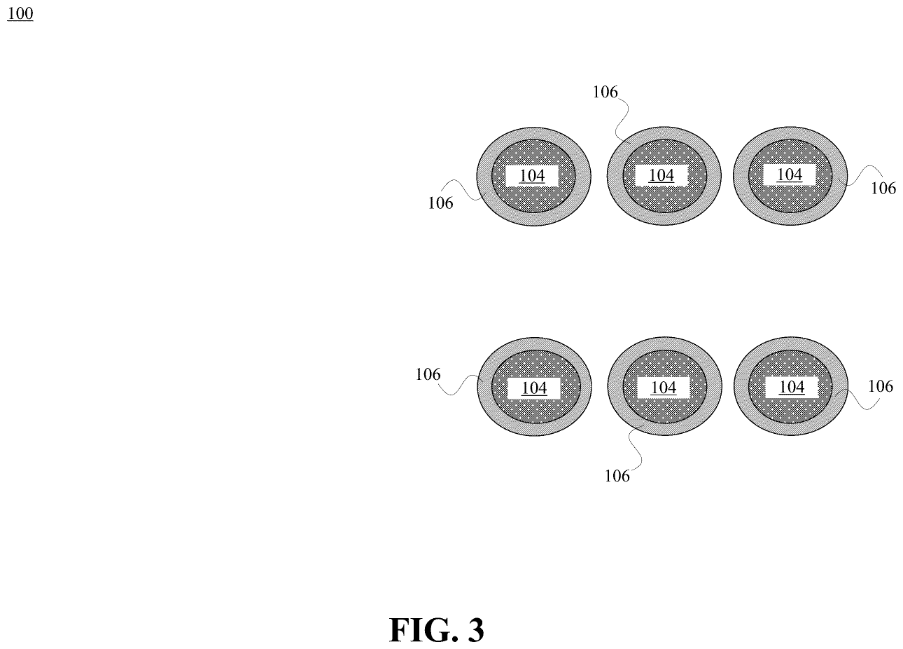

FIG. 3 depicts a top-down view of semiconductor device 100 that is to include nonlinear channel 110 at another stage of the fabrication process, according to embodiments of the disclosure. At the present fabrication stage, a sidewall image transfer (SIT) spacer 106 is formed upon the nonlinear sidewall(s) of the fin mandrel 104 and upon the top surface of hard mask.

The SIT spacer 106 may be a conformal film and can be deposited and then followed by an etchback process (e.g., ME). The deposition of material upon the mandrel 104 may also be referred to as spacer formation around vertical sides of each mandrel 104. The SIT spacer 106 material can include, but is not limited, an oxide, such as silicon oxide (SiOₓ) (where x is, for example, 2 in the case of silicon dioxide (SiO₂), or 1.99 or 2.01), formed by low-pressure chemical vapor deposition (LPCVD), PECVD, sub-atmospheric chemical vapor deposition (SACVD), rapid thermal chemical vapor deposition (RTCVD), in-situ radical assisted deposition, high temperature oxide (HTO) deposition, low temperature oxide (LTO) deposition, ozone/TEOS deposition, limited reaction processing CVD (LRPCVD). Alternatively, some other dielectric materials, such as SiOCN, SiCN, SiOC, can be used as the material for SIT spacer 106. A height of the mandrels 104 and corresponding SIT spacer 106 can be in the range of, but is not necessarily limited to, 30 nm to 100 nm.

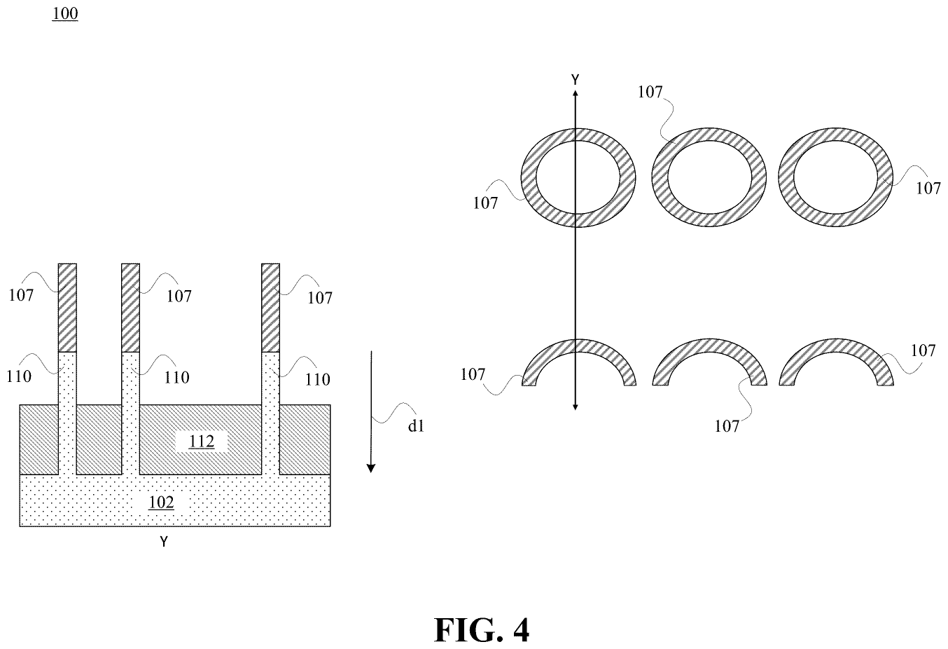

FIG. 4 depicts a top-down view and cross-sectional view of semiconductor device 100 that includes nonlinear channel 110 at another stage of the fabrication process, according to embodiments of the disclosure. At the present fabrication stage, the one or more mandrels 104 are removed, the one or more nonlinear channels 110 are formed, and one or more isolation regions 112 are formed.

Nonlinear channels 110 may be formed by patterning part of the semiconductor substrate 102 into the nonlinear channels 110. The nonlinear channels 110 may be formed by removal of the mandrels 104 to form openings. The openings expose portions of a top surface of the hard mask and are formed using an etching process such as, for example, a plasma dry etch.

The nonlinear channels 110 are formed by patterning part of the semiconductor substrate 102 into the nonlinear channels 110. The selective removal of the mandrels 104 leaves the SIT spacer 106 on the hard mask. The hard mask is patterned into a plurality of patterned hard mask portions 107 corresponding to the locations of the overlying the SIT spacer 106 so that the underlying patterned hard mask portions 107 have the same shape as the above the SIT spacer 106. More specifically, exposed portions of the hard mask not under the SIT spacer 106 (e.g., not masked by the SIT spacer 106) are removed using, for example, a directional etching process, comprising RIE using CF8, CH2F2 or other chemistry as is known to etch, for example, silicon nitride selective to other materials. The patterning of the hard mask into the plurality of patterned hard mask portions 107 spaced apart from each other can be performed using, for example, SAMP techniques, including, but not necessarily limited to, SADP, SAQP and SAOP.

Following removal of the SIT spacer 106, using the patterned hard mask portions 107 as masks, exposed portions of the semiconductor substrate 102 not covered by the hard mask portions 107 are removed to certain depth dl (depending on design) using a substrate etch. The substrate etch transfers the pattern of the hard mask portions 107 to the semiconductor substrate 102 to form the nonlinear channels 110, which have the same shape as the overlying hard mask portions 107. In accordance with an embodiment, semiconductor substrate 102 including a semiconductor material, such as, Si, SiGe, SiC, Si:C, SiGeC, SiGe:C, III-V, II-V compound semiconductor or other like semiconductor, can be selectively etched with respect to the hard mask portions 107 using, for example, a silicon RIE process.

While embodiments of the present disclosure describe channels as fins, the embodiments are not necessarily limited to fin channels, and may include nanowire channels, or the like. In addition, although a finite number of nonlinear channels 110 are shown in the figures for ease of explanation, more or fewer nonlinear channels 110 can be formed.

After nonlinear channel 110 formation, hard mask portions 107 may be removed and/or isolation regions 112 (e.g., shallow trench isolation (STI) regions) may be formed. After the selective removal of portions of the semiconductor substrate 102 to the depth d1, a plurality of trenches or patterns are formed in the semiconductor substrate 102, by for example, wet or dry etch processes. Dielectric material including, but not necessarily limited to SiOₓ, LTO, HTO, flowable oxide (FOX), silicon oxycarbide (SiOC), silicon oxycarbonitride (SiOCN) or some other dielectric, is deposited in the trenches or patterns. The dielectric material can be deposited using deposition techniques including, but not necessarily limited to, CVD, plasma enhanced CVD, PECVD, RFCVD, PVD, ALD, MLD, MBD, PLD, LSMCD, and/or sputtering to define the isolation regions 112. As depicted, top surfaces of the isolation regions 112 are below top surfaces of the one or more nonlinear channels 110.

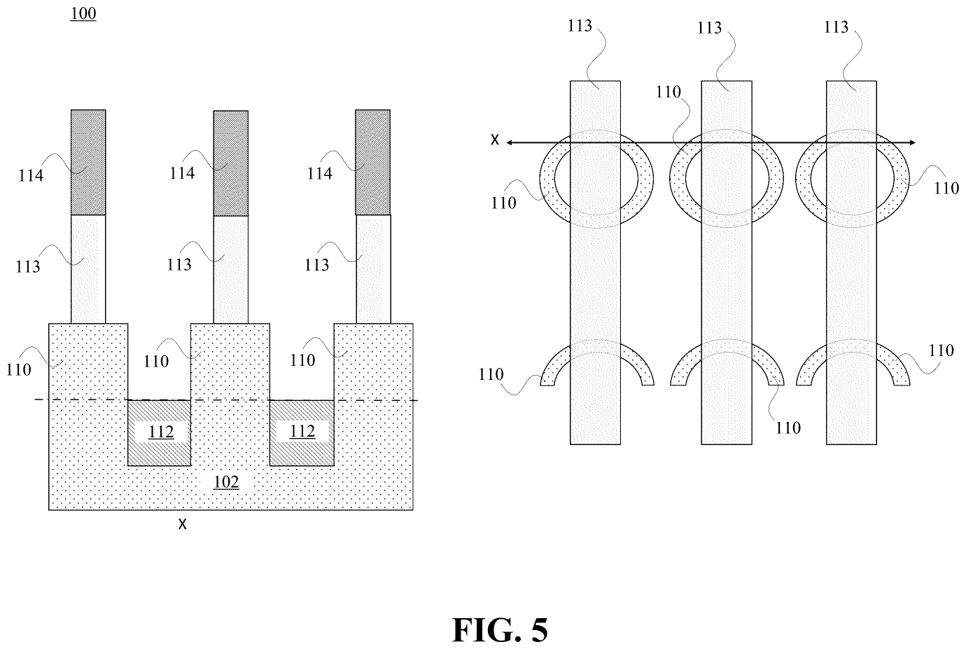

FIG. 5 depicts a top-down view and cross-sectional view of semiconductor device 100 that includes nonlinear channel 110 at another stage of the fabrication process, according to embodiments of the disclosure. At the present fabrication stage, one or more sacrificial gate structures are formed.

The one or more sacrificial gate structures may be formed upon and around the one or more nonlinear channels 110 and upon isolation regions 112. Sacrificial gate structure may include a gate liner (not shown), a sacrificial gate 113, and a sacrificial gate cap 114.

The sacrificial gate structure may be formed by initially forming a gate liner layer (e.g., a dielectric, oxide, or the like) upon isolation regions 112 and upon and around f the one or more nonlinear channels 110. For instance, the gate liner layer may be deposited upon the upper surface of isolation regions 112, sidewalls of the one or more nonlinear channels 110, upper surfaces of the one or more nonlinear channels 110, or the like. The sacrificial gate structure may further be formed by subsequently forming a sacrificial gate layer (e.g., a dielectric, amorphous silicon, or the like) upon the gate liner. The thickness of the sacrificial gate layer may be greater than the height of the one or more nonlinear channels 110.

The sacrificial gate structure 160 may further be formed by subsequently forming a gate cap layer upon the sacrificial gate layer. The gate cap layer may be formed by depositing a mask material, such as a hard mask material. The gate cap layer may be composed of one or more layers masking materials to protect the sacrificial gate layer and/or other underlying materials during subsequent processing of device 100. The gate cap layer can be formed of gate mask materials such as silicon nitride, silicon oxide, combinations thereof, or the like.

The gate cap layer, sacrificial gate layer, and gate liner may be patterned using lithography and etch process to remove undesired portions and retain desired portion(s), respectively. The retained desired portion(s) of the gate cap layer, sacrificial gate layer, and gate liner layer may form the gate liner, the sacrificial gate 113, and the sacrificial gate cap 114, respectively, of each of the one or more sacrificial gate structures.

Each sacrificial gate structure can be formed on targeted regions or areas of semiconductor device 100 to define the length of one or more transistors, and to provide sacrificial material for yielding targeted transistor structure(s) in subsequent processing. According to an example, each sacrificial gate structure can have a height of between approximately 50 nm and approximately 200 nm, and a length of between approximately 15 nm and approximately 200 nm.

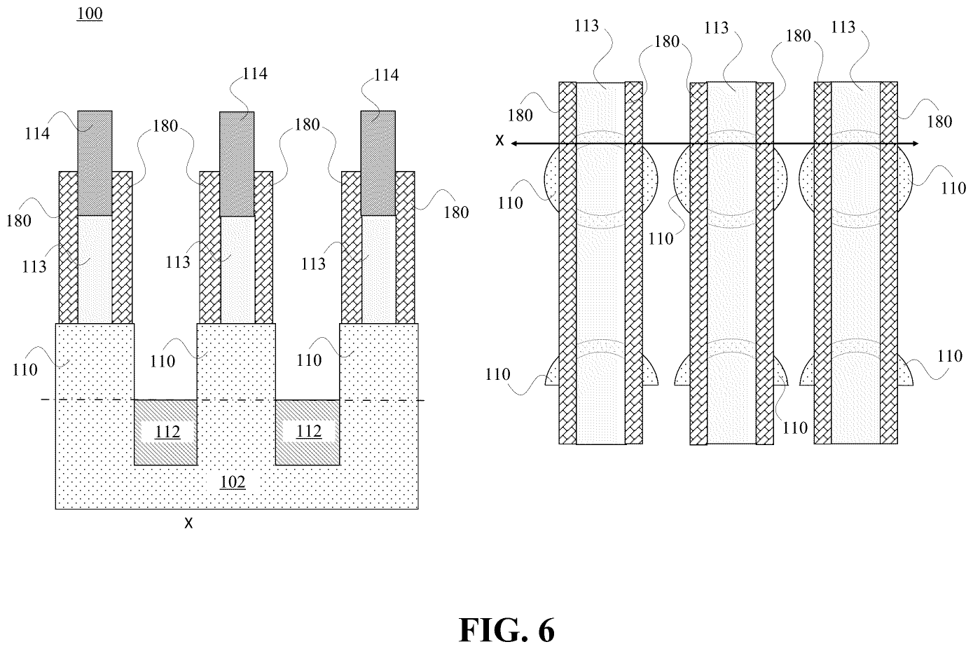

FIG. 6 depicts a top-down view and cross-sectional view of semiconductor device 100 that includes nonlinear channel 110 at another stage of the fabrication process, according to embodiments of the disclosure. At the present fabrication stage, one or more gate spacers 180 are formed.

The one or more gate spacers 180 may be formed upon at least respective side surfaces of the sacrificial gate structure(s), upon and around exposed portion(s) of nonlinear channel 110, and upon isolation regions 112. The gate spacer(s) 180 may further be formed upon end surface(s) of the associated sacrificial gate structure(s). The gate spacer(s) 180 may be formed by a conformal deposition of a dielectric material, such as silicon nitride, SiBCN, SiNC, SIN, SiCO, SiNOC, or a combination thereof, or the like. Undesired portion(s) of the dielectric material may be removed by an anisotropic etching process. Desired portion(s) of the dielectric material may be retained upon the sidewalls of the sacrificial gate structure(s).

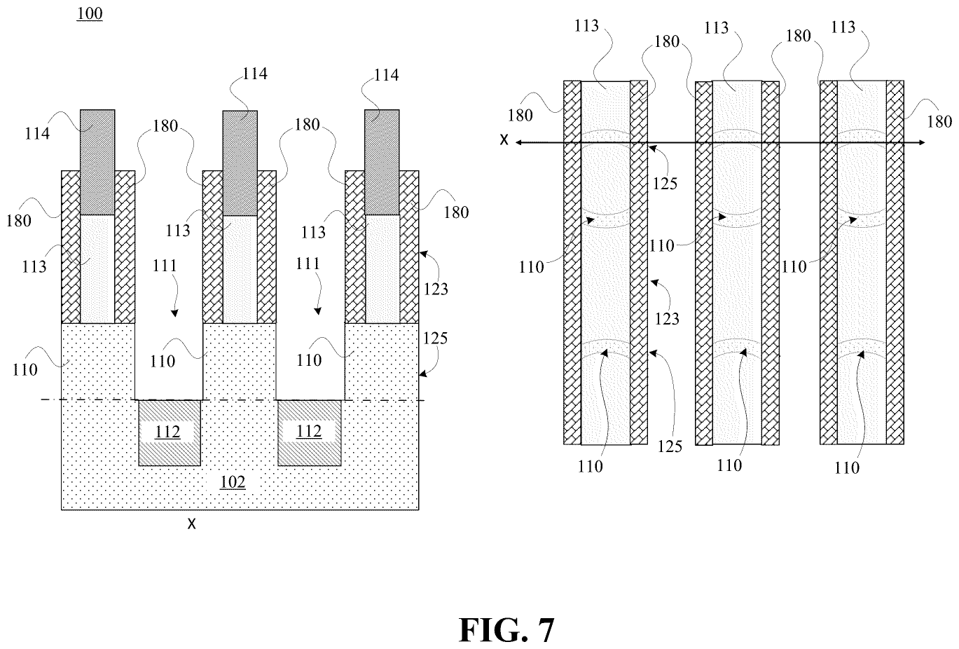

FIG. 7 depicts a top-down view and cross-sectional view of semiconductor device 100 that includes nonlinear channel 110 at another stage of the fabrication process, according to embodiments of the disclosure. At the present fabrication stage, portion(s) of nonlinear channel 110 that are not covered by gate spacer(s) 180 may be recessed or otherwise removed.

Nonlinear channel 110 may be recessed by a directional etch, or the like to remove portions of the nonlinear channel(s) 110 that are not covered by gate spacer(s) 180. The top surface of isolation regions 112 may be utilized as an etch stop and the gate spacer(s) 180 may be retained. Subsequently, a respective end surface 125 of nonlinear channel 110 may be coplanar with a side surface 123 of gate spacer 180. Trimming or removal of portion(s) of nonlinear channel(s) 110 may form one or more source/drain (S/D) openings 111. The one or more of the S/D openings 111 may be defined or bounded by the top surface of isolation regions 112 and at least one or more opposing and facing end surfaces 125 of adjacent nonlinear channels 110. The one or more of the S/D openings 111 may be further defined or bounded by opposing and facing respective sections of side surface 123 of gate spacer 180.

For clarity, there may be two distinct patterned nonlinear channels 310 fabricated from one fin structure around one common mandrel. For example, as depicted in the top-down views, the upper FETs include a first channel and second channel that share a same central axis of curvature.

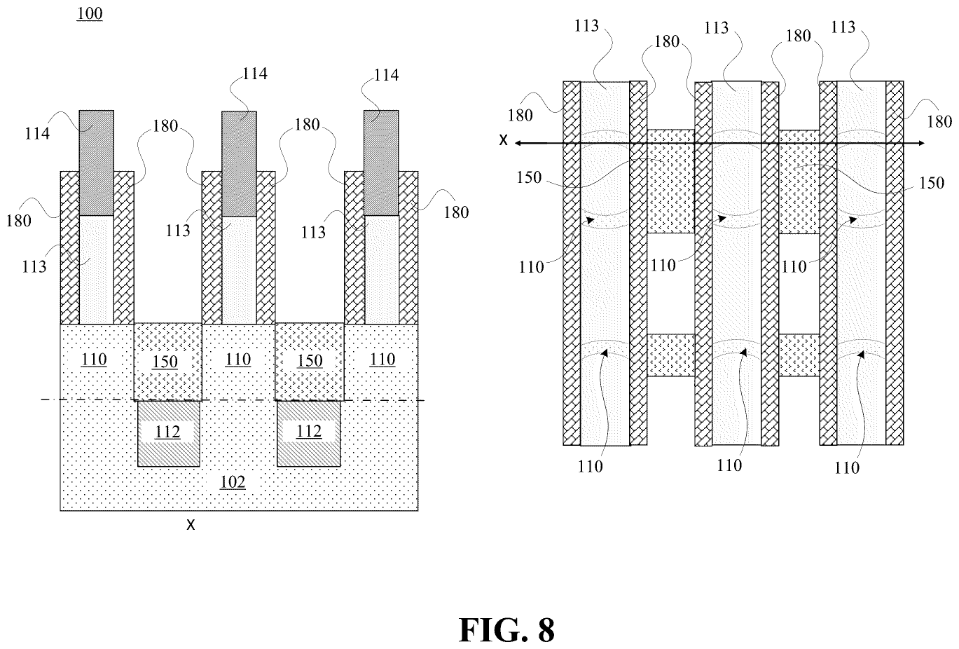

FIG. 8 depicts a top-down view and cross-sectional view of semiconductor device 100 that includes nonlinear channel 110 at another stage of the fabrication process, according to embodiments of the disclosure. At the present fabrication stage, a S/D region 150 is formed in one or more S/D openings 111, respectively.

S/D region 150 may be formed by epitaxially growing a source/drain epitaxial region within S/D opening 111, e.g., from exposed end surface(s) 125 of one or more nonlinear channels 110. In some embodiments, the S/D region 150 is formed by in-situ doped epitaxial growth. In some embodiments, epitaxial growth and/or deposition processes may be selective to forming on semiconductor surfaces, and may not deposit material on dielectric surfaces, such as silicon dioxide or silicon nitride surfaces.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si:C for n-type transistors. The doping concentration in S/D region 150 can be in the range of 1×1019 cm−3 to 2×1021 cm−3, or preferably between 2×1020 cm−3 to 7×1020 cm−3.

In certain implementations, S/D region 150 may be grown such that a bottom surface contacts isolation regions 112 and an upper surface of the S/D region 150 is above the upper surface of nonlinear channel 110. For clarity, as depicted in the X cross sectional view, a first S/D region 150 may be a source region for nonlinear channel 110 and a second S/D region 150 may be a drain region for nonlinear channel 110. Further, as depicted in the top down view, two different S/D regions 150 grown from distinct nonlinear channels 110 may effectively merge and form a single S/D region 150 that may serve as the source or drain of the distinct nonlinear channels 110.

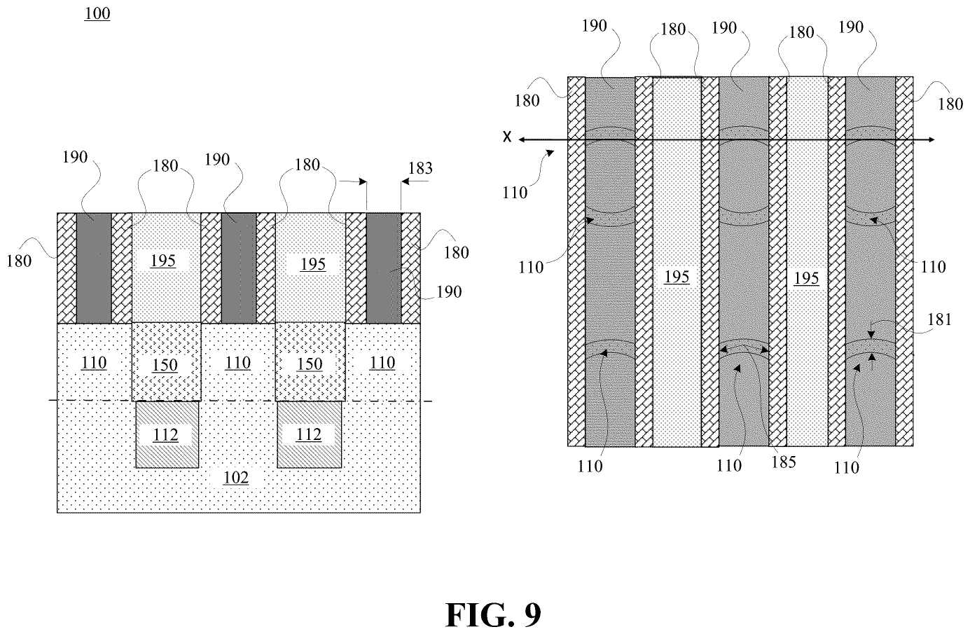

FIG. 9 depicts a top-down view and cross-sectional view of semiconductor device 100 that includes nonlinear channel 110 at another stage of the fabrication process, according to embodiments of the disclosure. At the present fabrication stage, interlayer dielectric 195 is formed upon isolation regions 112 and upon S/D regions 150, sacrificial gate 113 is removed, and replacement gate 190 is formed in place thereof.

Interlayer dielectric 195 may be formed on the one or more S/D regions 150 and upon the top surface of isolation regions 112. Interlayer dielectric 195 may be formed by depositing a dielectric material, such as silicon oxide, silicon nitride, SiBCN, SiNC, SIN, SiCO, SiNOC, or a combination thereof, or the like, as a blanket layer over isolation regions 112, S/D regions 150, and upon gate spacers 180. In an embodiment, interlayer dielectric 195 may be formed to a thickness above the top surface of semiconductor device 100 and subsequently planarized by a chemical mechanical polish (CMP) or etch, such that the top surface of sacrificial gate 113 is exposed (e.g., sacrificial gate cap 114 is removed by the CMP) and is coplanar with a top surface of the sacrificial interlayer dielectric 195 and with a top surface of gate spacers 180.

Upon exposing a portion of the sacrificial gate 113, the sacrificial gate 113 is removed by an etch. The removal of sacrificial gate 113 may expose the nonlinear channel 110 between gate spacers 180 previously associated therewith, may expose the gate dielectric thereunder, and/or the like.

A replacement gate structure is then formed in place of the removed sacrificial gate 113 in between gate spacers 180 and upon and around nonlinear channel 110. The replacement gate structure can include the gate dielectric (not shown) and replacement gate 190. The gate dielectric be the gate dielectric associated with the replacement gate structure or if removed, a subsequent gate dielectric that can comprise any suitable dielectric material, including but not limited to silicon oxide, silicon nitride, silicon oxynitride, high-k materials, or any combination of these materials. The gate dielectric can be formed by any suitable deposition process or the like. In some embodiments, the gate dielectric has a thickness ranging from 1 nm to 5 nm, although less thickness and greater thickness are also conceived.

Replacement gate 190 can comprise any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAlC), tungsten silicide (WSi), tungsten nitride (WN), ruthenium oxide (RuO2), cobalt silicide (CoSi), nickel silicide (NiSi)), transition metal aluminides (e.g. Ti3Al, ZrAl), TaC, TaMgC, carbon nanotube, conductive carbon, graphene, or any suitable combination of these materials.

Replacement gate 190 may further comprise dopants that are incorporated during or after deposition. In some embodiments, the replacement gate 190 may further comprise a workfunction setting layer (not shown) between the gate dielectric and the replacement gate 190. The workfunction setting layer can be a workfunction metal (WFM). The replacement gate 190 and WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc.

The replacement gate structure may be formed by initially forming the gate dielectric layer between gate spacers around the nonlinear channel 110 and upon the top surface of isolation regions. The replacement gate structure may further be formed by subsequently forming a gate conductor layer upon the gate dielectric layer. The gate conductor layer and gate dielectric layer may be patterned using lithography and etch process to remove undesired portions and retain desired portion(s), respectively. The retained desired portion(s) of the gate conductor layer and gate dielectric layer may form the replacement gate dielectric layer and replacement gate 190, respectively. A CMP, etch process, or another subtractive removal technique, may remove undesired portions of replacement gate structure, such that a top surface of replacement gate structure is coplanar with the top surface of gate spacer 180, interlayer dielectric 195, or the like. In some implementations, replacement gate 190 can be recessed below the top surface of semiconductor device 100 and a dielectric gate cap (not shown) can be formed upon the recessed replacement gate 190.

For clarity, to achieve expected finFET functionality, the replacement gate 190 electric field of semiconductor device 100 generally controls the nonlinear channel 110 and the drain (e.g., one of the S/D regions 150) electric field has a lesser effect on the nonlinear channel 110. Nonlinear channel 110 includes arced, curved, segmented, or the like, sidewall(s) that define a nonlinear channel or fin width 181. As depicted, nonlinear channel or fin width 181 may be constant across the channel or fin length 185 underneath the replacement gate 190. The nonlinearity of nonlinear channel 110 results in a relatively increased channel or fin length 185 compared to a linear fin with the same fin width. As such, the channel or fin length 185 of the nonlinear channel 110 may be relatively increased within the confines of the footprint (e.g., gate length (Lg) 183 by gate width) of the replacement gate 190. In other words, short channel effects may be limited due to a reduced electric field along the nonlinear channel 110 due to the relatively increased channel or fin length 185 within the footprint of the replacement gate 190.

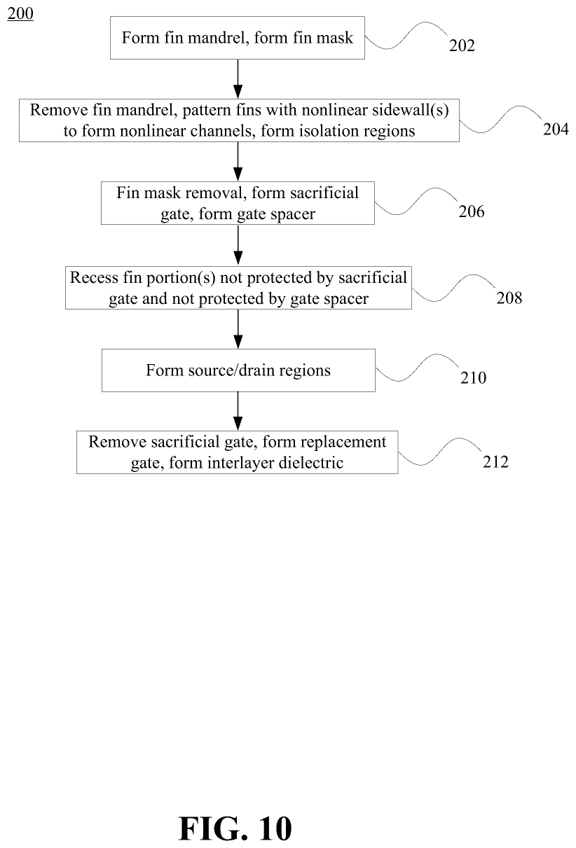

FIG. 10 depicts a method 200 of fabricating semiconductor device 100 that includes nonlinear channel 110, according to embodiments of the disclosure. Method 200 begins at block 202 by forming one or more fin mandrels 104 and one or more SIT spacers 106 over substrate 102. Method 200 continues, at block 204, with removing the one or more fin mandrels 104, pattering fins that include nonlinear sidewalls to effectively form nonlinear channels 110, and forming isolation regions 112. Method 200 continues, at block 206, with removing the one or more SIT spacers 106, with forming one or more sacrificial gate structures, and with forming gate spacer 108 on the sidewalls of the respective one or more sacrificial gate structures.

Method 200 continues, at block 208, with recessing one or more portions of the fin(s) that are not protected by the sacrificial gate structure and/or are not protected by the gate spacer 108. Method 200 continues, at block 210, with forming respective S/D regions 150 on or in physical contact with opposing end surfaces of one or more nonlinear channel(s) 110. Method 200 may continue with removing the sacrificial gate structure between gate spacers 108, forming a replacement gate structure in place thereof around the nonlinear channel 110 and between gate spacers 108, and forming interlayer dielectric 195.

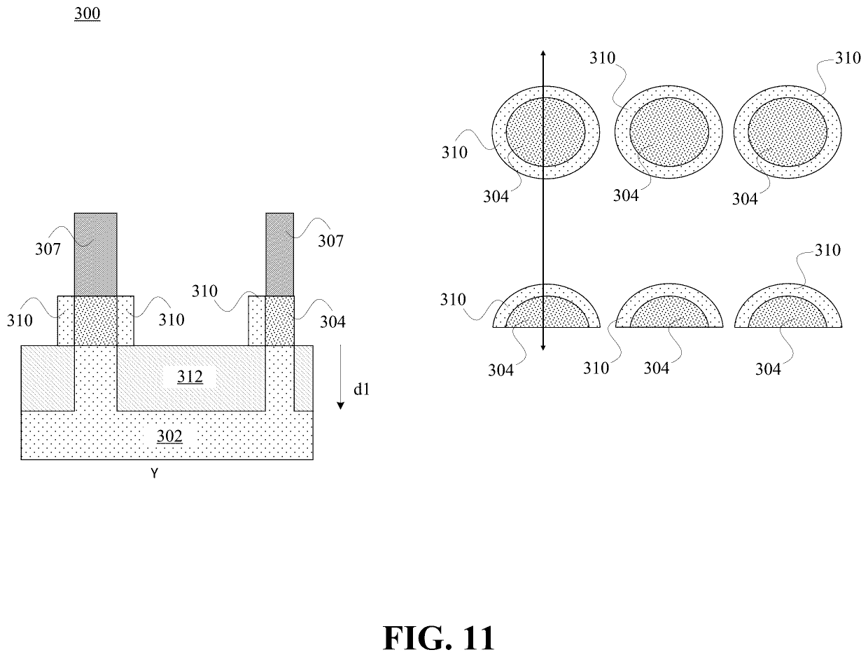

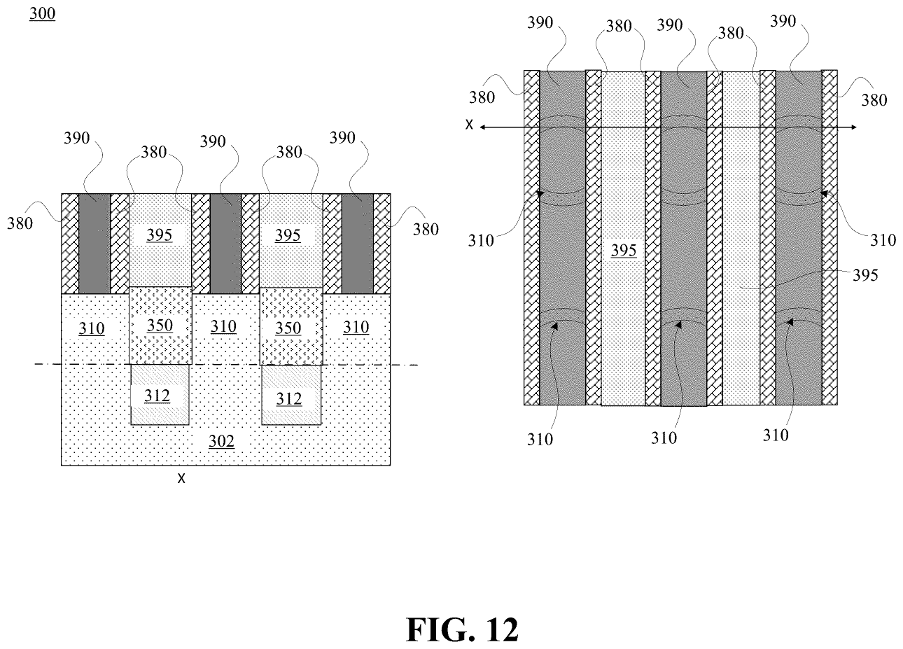

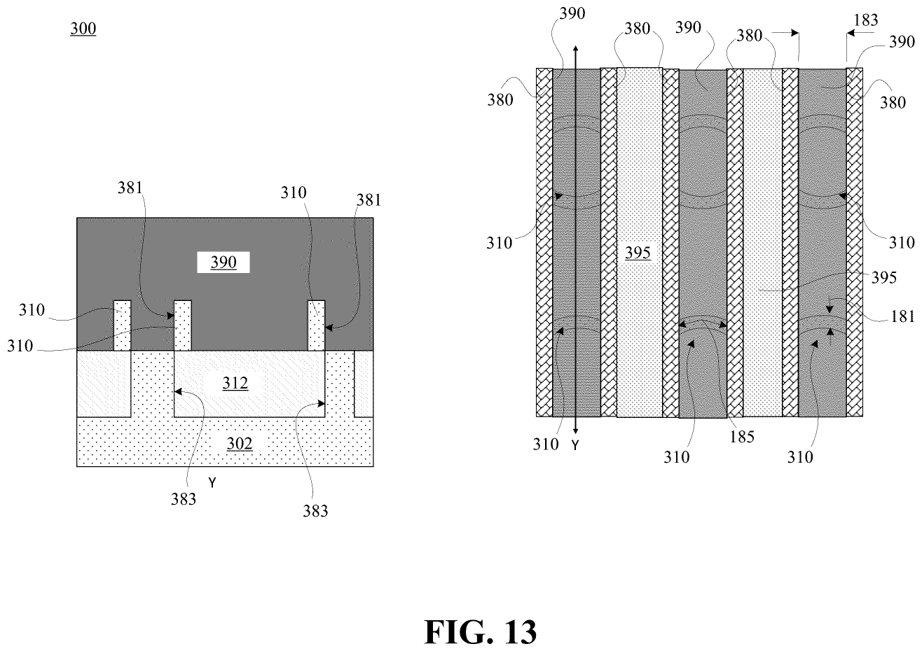

Referring now to FIG. 11 which depicts a cross-sectional view and top-down view of a semiconductor device 300 that includes a nonlinear channel 310, according to embodiments of the disclosure. Semiconductor device 300 may further include semiconductor substrate 302, one or more isolation regions 312, one or more source/drain (S/D) 350 (depicted, for example, in FIG. 12), one or more replacement gate 390 (depicted, for example, in FIG. 12 and in FIG. 13), one or more gate spacers 380 (depicted, for example, in FIG. 12), and one or more interlayer dielectric 395 (depicted, for example, in FIG. 12).

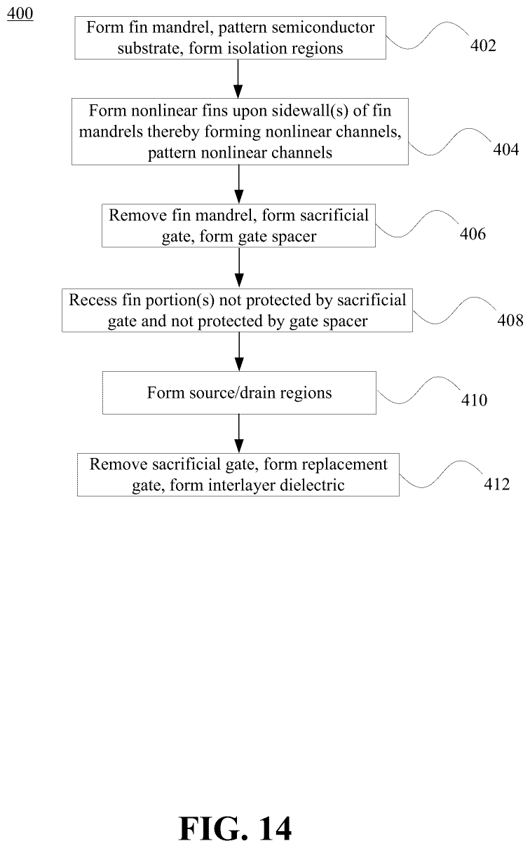

Nonlinear channel 310 may include generally arced, curved, segmented, or the like, sidewall(s) that form a nonlinear channel and that define the fin width 181 and channel length 185, exemplarity depicted in FIG. 14. Specifically, as depicted, nonlinear channel 310 may include arced or curved sidewalls that define the fin or channel width 181. The nonlinear channel generally has a longer fin or channel length 185 relative to a channel that includes linear sidewalls of a typical fin (i.e., sidewalls parallel to the X-plane, as depicted). As such, the channel length 185 of the nonlinear channel 310 may be relatively increased within the confines of the replacement gate footprint (e.g., within the gate length (Lg) 183 exemplarity depicted in FIG. 14 of the replacement gate 390). In other words, the channel length 185 of the nonlinear channel 310 may be relatively increased without also increasing the gate length (Lg) 183 of the replacement gate 390. Though shown with arced or curved sidewalls, nonlinear channel 310 may include V-shaped sidewalls, hexagonal sidewalls, or the like that define the fin or channel width 181 and the fin or channel length 185.

FIG. 11 depicts a top-down view and cross-sectional view of semiconductor device 300 that is to include nonlinear channel 310 after fabrication process, according to embodiments of the disclosure. At the present fabrication stages, one or more fin mandrels 304 may be formed upon over semiconductor substrate 302, nonlinear channels 310 may be formed upon sidewall(s) of the one or more fin mandrels 304, one or more nonlinear channels 310 may be patterned, and one or more isolation regions 320 may be formed.

Semiconductor substrate 302 includes the same or similar semiconductor material(s) and/or structures relative to semiconductor substrate 102. The one or more fin mandrels 304 comprise, but are not necessarily limited to, amorphous silicon (a-Si), amorphous carbon, polycrystalline silicon, polycrystalline silicon germanium, amorphous silicon germanium, polycrystalline germanium, and/or amorphous germanium, are formed on substrate 302. In one embodiment, the one or more fin mandrels 304 are formed by depositing or epitaxially growing the appropriate material(s) upon substrate 302 as a blanket mandrel layer, by depositing a mandrel mask layer (not shown) upon the blanket mandrel layer and patterning the mandrel mask layer and underlying blanket mandrel layer using lithography and etching techniques. Portions of the blanket mandrel layer and the mandrel hard mask layer are removed and desired portions of the blanket mandrel layer and the mandrel hard mask layer are retained, thereby forming the one or more fin mandrels 304 with a hard mask portion 307 thereupon, as depicted.

The one or more fin mandrels 304 may be spaced apart from each other. In an example, fin mandrel 304 may be a circular column and have a circular sidewall that has one center axis located into and out of the page of the top-down view of FIG. 11. In this example, nonlinear channels 310 that are fabricated associated therewith may also have circular sidewalls that define the fin width 181. In another example, as depicted, each mandrel 304 may be an oblong oval column and have an arced sidewall that has two focal axes that are located into and out of the page of the top-down view of FIG. 11. In this example, nonlinear channels 310 that are fabricated associated therewith may also have oval arced sidewalls that define the fin width 181. In another example, each mandrel 304 may be a diamond column and have segmented sidewalls with respect to the top-down view of FIG. 11. In this example, nonlinear channels 310 that are fabricated associated therewith may also have V-shaped segmented sidewalls that define the fin width 181. In another example, each mandrel 304 may be polygonal column (e.g., hexagonal column, etc.) that has one central bisector axis, into and out of the page of the top-down view of FIG. 11 and has associated segmented sidewalls. In this example, nonlinear channels 310 that are fabricated associated therewith may also have polygonal segmented sidewalls that define the fin width 181.

After mandrel 304 formation, using the mandrel 304 and/or hard mask portions 307 as masks, exposed portions of the semiconductor substrate 302 not covered by the mandrel(s) 304 and hard mask portions 307 are removed to certain depth d1 (depending on design) using a substrate etch. The substrate etch transfers the pattern of the mandrel 304 and hard mask portions 307 to the semiconductor substrate 302. In accordance with an embodiment, semiconductor substrate 302 including a semiconductor material, such as, Si, SiGe, SiC, Si:C, SiGeC, SiGe:C, III-V, II-V compound semiconductor or other like semiconductor, can be selectively etched with respect to the hard mask portions 307 and fin mandrels 304, using, for example, a silicon RIE process.

After hard mask portions 307 and fin mandrels 304 formation, isolation regions 312 (e.g., shallow trench isolation (STI) regions) may be formed. After the selective removal of portions of the semiconductor substrate 302 to the depth d1, a plurality of trenches or patterns are formed in the semiconductor substrate 302, by for example, wet or dry etch processes. Dielectric material including, but not necessarily limited to SiOₓ, LTO, HTO, flowable oxide (FOX), silicon oxycarbide (SiOC), silicon oxycarbonitride (SiOCN) or some other dielectric, is deposited in the trenches or patterns. The dielectric material can be deposited using deposition techniques including, but not necessarily limited to, CVD, plasma enhanced CVD, PECVD, RFCVD, PVD, ALD, MLD, MBD, PLD, LSMCD, and/or sputtering to define the isolation regions 312. As depicted, top surfaces of the isolation regions 312 may be coplanar with the top surface of substrate 302.

The one or more nonlinear channels 310 may be formed by epitaxially growing semiconductor material, such as Silicon, Silicon Germanium, or the like, from the sidewall(s) of the one or more fin mandrels 304. In some embodiments, epitaxial growth and/or deposition processes may be selective to forming on semiconductor surfaces, and may not deposit material on dielectric surfaces, such as silicon dioxide or silicon nitride surfaces. For example, the epitaxially grown semiconductor material may grow from the exposed sidewalls of fin mandrels 104 but not from the exposed surfaces of isolation regions 312, from the exposed surfaces of hard mask portions 307, or the like.

While embodiments of the present disclosure describe the nonlinear channels 310 as fins, the embodiments are not necessarily limited to fin channels, and may include nanowire channels, or the like. In addition, although a finite number of nonlinear channels 310 are shown in the figures for ease of explanation, more or fewer nonlinear channels 310 can be formed.

In examples, one or more fin mandrels 304 and respective nonlinear channel(s) 310 formed therearound may be patterned. For example, as depicted in the top-down view a first portion of fin mandrels 304 and respective nonlinear channel(s) 310 formed therearound may be removed while a second portion of fin mandrels 304 and respective nonlinear channel(s) 310 formed therearound may be retained. The fin mandrels 304 and respective nonlinear channel(s) 310 formed therearound may be patterned using lithography and etch process to remove undesired portions and retain desired portion(s), respectively. Subsequently, the one or more fin mandrels 304 and respective hard mask portions 307 may be removed while the nonlinear channel(s) 310 formed therearound may be retained upon the top surface of isolation regions 312.

At a subsequent fabrication stage, one or more sacrificial gate structures may be formed. The one or more sacrificial gate structures may be formed upon and around the one or more nonlinear channels 310, upon substrate 302, and upon isolation regions 312. Sacrificial gate structure may include a gate liner (not shown), a sacrificial gate (not shown), and a sacrificial gate cap (not shown). The sacrificial gate structure may be formed by initially forming a gate liner layer (e.g., a dielectric, oxide, or the like) upon isolation regions 312, upon semiconductor substrate 302, and upon and around the one or more nonlinear channels 310. For instance, the gate liner layer may be deposited upon the upper surface of isolation regions 312, upper surface of semiconductor substrate 302, sidewalls of the one or more nonlinear channels 310, upper surfaces of the one or more nonlinear channels 310, or the like. The sacrificial gate structure may further be formed by subsequently forming a sacrificial gate layer (e.g., a dielectric, amorphous silicon, or the like) upon the gate liner. The thickness of the sacrificial gate layer may be greater than the height of the one or more nonlinear channels 310.

The sacrificial gate structure may further be formed by subsequently forming a gate cap layer upon the sacrificial gate layer. The gate cap layer may be formed by depositing a mask material, such as a hard mask material. The gate cap layer may be composed of one or more layers masking materials to protect the sacrificial gate layer and/or other underlying materials during subsequent processing of device 300. The gate cap layer can be formed of gate mask materials such as silicon nitride, silicon oxide, combinations thereof, or the like.

The gate cap layer, sacrificial gate layer, and gate liner may be patterned using lithography and etch process to remove undesired portions and retain desired portion(s), respectively. The retained desired portion(s) of the gate cap layer, sacrificial gate layer, and gate liner layer may form the gate liner, the sacrificial gate, and the sacrificial gate cap, respectively, of each of the one or more sacrificial gate structures.

Each sacrificial gate structure can be formed on targeted regions or areas of semiconductor device 300 to define the length of one or more transistors, and to provide sacrificial material for yielding targeted transistor structure(s) in subsequent processing. According to an example, each sacrificial gate structure can have a height of between approximately 50 nm and approximately 200 nm, and a length of between approximately 15 nm and approximately 200 nm.

At another stage one or more gate spacers 380, exemplarity depicted in FIG. 12, are formed. The one or more gate spacers 380 may be formed upon at least respective side surfaces of the sacrificial gate structure(s), upon and around exposed portion(s) of nonlinear channel 310, upon the semiconductor substrate 302, and upon isolation regions 312. The gate spacer(s) 380 may further be formed upon end surface(s) of the associated sacrificial gate structure(s). The gate spacer(s) 380 may be formed by a conformal deposition of a dielectric material, such as silicon nitride, SiBCN, SiNC, SIN, SiCO, SiNOC, or a combination thereof, or the like. Undesired portion(s) of the dielectric material may be removed by an anisotropic etching process. Desired portion(s) of the dielectric material may be retained upon the sidewalls of the sacrificial gate structure(s).

At another fabrication stage, portion(s) of nonlinear channel 310 that are not covered by gate spacer(s) 380 may be recessed or otherwise removed. These portions of nonlinear channel 310 may be recessed by a directional etch, or the like to remove portions of the nonlinear channel(s) 310 that are not covered by gate spacer(s) 380. The top surface of isolation regions 312 may be utilized as an etch stop and the gate spacer(s) 380 may be retained. Subsequently, a respective end surface of nonlinear channel 110 may be coplanar with an outer side surface of gate spacer 380. Trimming or removal of portion(s) of nonlinear channel(s) 310 may form one or more source/drain (S/D) openings. The one or more of the S/D openings may be defined or bounded by the top surface of isolation regions 312 and at least one or more opposing and facing end surfaces of adjacent nonlinear channels 310. The one or more of the S/D openings may be further defined or bounded by opposing and facing respective sections of side surface of gate spacer 380.

FIG. 12 depicts a top-down view and cross-sectional view of semiconductor device 300 that includes nonlinear channel 310 after fabrication process, according to embodiments of the disclosure. FIG. 13 depicts a top-down view and cross-sectional view of semiconductor device 300 that includes nonlinear channel 310 after fabrication process, according to embodiments of the disclosure. At the present fabrication stages, a S/D region 350 is formed in one or more S/D openings, respectively, interlayer dielectric 395 is formed upon isolation regions 312 and upon S/D regions 350, sacrificial gate is removed, and replacement gate 390 is formed in place thereof.

S/D region 350 may be formed by epitaxially growing a source/drain epitaxial region within S/D opening, e.g., from the exposed end surface(s) of one or more nonlinear channels 310. In some embodiments, the S/D region 350 is formed by in-situ doped epitaxial growth. In some embodiments, epitaxial growth and/or deposition processes may be selective to forming on semiconductor surfaces, and may not deposit material on dielectric surfaces, such as silicon dioxide or silicon nitride surfaces.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si:C for n-type transistors. The doping concentration in S/D region 350 can be in the range of 1×1019 cm−3 to 2×1021 cm−3, or preferably between 2×1020 cm−3 to 7×1020 cm−3.

In certain implementations, S/D region 350 may be grown such that a bottom surface contacts isolation regions 312 and an upper surface of the S/D region 350 is above the upper surface of nonlinear channel 310. For clarity, as depicted in the X cross sectional view of FIG. 12, a first S/D region 350 may be a source region for nonlinear channel 310 and a second S/D region 350 may be a drain region for nonlinear channel 310. For clarity, two different S/D regions 350 grown from distinct nonlinear channels 310 may effectively merge and form a single S/D region 350 that may serve as the source or drain of the distinct nonlinear channels 310.

At another fabrication stage, interlayer dielectric 395 is formed upon isolation regions 312 and upon S/D regions 350, sacrificial gate is removed, and replacement gate 390 is formed in place thereof.

Interlayer dielectric 395 may be formed on the one or more S/D regions 350 and upon the top surface of isolation regions 312. Interlayer dielectric 395 may be formed by depositing a dielectric material, such as silicon oxide, silicon nitride, SiBCN, SiNC, SIN, SiCO, SiNOC, or a combination thereof, or the like, as a blanket layer over isolation regions 312, S/D regions 350, and upon gate spacers 380. In an embodiment, interlayer dielectric 395 may be formed to a thickness above the top surface of semiconductor device 300 and subsequently planarized by a chemical mechanical polish (CMP) or etch, such that the top surface of sacrificial gate is exposed (e.g., sacrificial gate cap is removed by the CMP) and is coplanar with a top surface of the sacrificial interlayer dielectric 395 and with a top surface of gate spacers 380.

Upon exposing a portion of the sacrificial gate, the sacrificial gate is removed by an etch. The removal of sacrificial gate may expose the nonlinear channel 310 between gate spacers 380 previously associated therewith, may expose the gate dielectric thereunder, and/or the like.

A replacement gate structure is then formed in place of the removed sacrificial gate in between gate spacers 380 and upon and around nonlinear channel 310. The replacement gate structure can include the gate dielectric (not shown) and replacement gate 390. The gate dielectric be the gate dielectric associated with the replacement gate structure or if removed, a subsequent gate dielectric that can comprise any suitable dielectric material, including but not limited to silicon oxide, silicon nitride, silicon oxynitride, high-k materials, or any combination of these materials. The gate dielectric can be formed by any suitable deposition process or the like. In some embodiments, the gate dielectric has a thickness ranging from 1 nm to 5 nm, although less thickness and greater thickness are also conceived.

Replacement gate 390 can comprise any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAIC), tungsten silicide (WSi), tungsten nitride (WN), ruthenium oxide (RuO2), cobalt silicide (CoSi), nickel silicide (NiSi)), transition metal aluminides (e.g. Ti3Al, ZrAl), TaC, TaMgC, carbon nanotube, conductive carbon, graphene, or any suitable combination of these materials.

Replacement gate 390 may further comprise dopants that are incorporated during or after deposition. In some embodiments, the replacement gate 390 may further comprise a workfunction setting layer (not shown) between the gate dielectric and the replacement gate 390. The workfunction setting layer can be a workfunction metal (WFM). The replacement gate 390 and WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc.

The replacement gate structure may be formed by initially forming the gate dielectric layer between gate spacers around the nonlinear channel 310 and upon the top surface of isolation regions 312. The replacement gate structure may further be formed by subsequently forming a gate conductor layer upon the gate dielectric layer. The gate conductor layer and gate dielectric layer may be patterned using lithography and etch process to remove undesired portions and retain desired portion(s), respectively. The retained desired portion(s) of the gate conductor layer and gate dielectric layer may form the replacement gate dielectric layer and replacement gate 390, respectively. A CMP, etch process, or another subtractive removal technique, may remove undesired portions of replacement gate structure, such that a top surface of replacement gate structure is coplanar with the top surface of gate spacer 380, interlayer dielectric 395, or the like. In some implementations, replacement gate 390 can be recessed below the top surface of semiconductor device 300 and a dielectric gate cap (not shown) can be formed upon the recessed replacement gate 390.

For clarity, as depicted in the cross-sectional view of FIG. 13, the nonlinear channel 310 may be formed over isolation regions 312 and the replacement gate structure may be formed over the semiconductor substrate that is below and directly adjacent to the footprint of the nonlinear channel 310. Further, a side surface 381 of nonlinear channel 310 may be coplanar with an opposing side surface 383 of substrate 302. Generally, the surface 381 is an oppositely facing surface relative to surface 383.

For further clarity, to achieve expected finFET functionality, the replacement gate 390 electric field of semiconductor device 300 generally controls the nonlinear channel 310 and the drain (e.g., one of the S/D regions 350) electric field has a lesser effect on the nonlinear channel 310. Nonlinear channel 310 includes arced, curved, segmented, or the like, sidewall(s) that define a nonlinear fin or channel width 181 and fin or channel length 185. As depicted, nonlinear fin or channel width 181 may be constant across the fin or channel length 185 underneath the replacement gate 390. The nonlinearity of nonlinear channel 310 results in a relatively increased channel or fin length 185 compared to a linear fin with the same fin width. As such, the channel or fin length 185 of the nonlinear channel 310 may be relatively increased within the confines of the footprint of the replacement gate 390. In other words, short channel effects may be limited due to a reduced electric field along the nonlinear channel 310 due to the relatively increased channel or fin length 185 within the footprint of the replacement gate 390.

FIG. 14 depicts a method 400 of fabricating semiconductor device 300 that includes nonlinear channel 310, according to embodiments of the disclosure. Method 400 begins at block 402 by forming one or more fin mandrels 304 over substrate 302, patterning or opening portions of the underlying semiconductor substrate 302 and forming isolation regions 312 within the patterns or openings within the semiconductor substrate 302.

Method 400 continues, at block 404, with forming nonlinear fins upon the sidewall(s) (thereby forming nonlinear channels 310) of the one or more fin mandrels 304 to form the one or more nonlinear channels 310. In examples, one or more of the nonlinear channels 310 may be patterned. Method 400 continues, at block 406, with removing the one or more fin mandrels 304, with forming one or more sacrificial gate structures, and with forming gate spacer 308 on the sidewalls of the respective one or more sacrificial gate structures.

Method 400 continues, at block 408, with recessing one or more portions of the nonlinear channels 310 that are not protected by the sacrificial gate structure and/or are not protected by the gate spacer 308. Method 400 continues, at block 410, with forming respective S/D regions 350 on or in physical contact with opposing end surfaces of one or more nonlinear channel(s) 310. Method 400 may continue with removing the sacrificial gate structure between gate spacers 308, forming a replacement gate structure in place thereof around the nonlinear channel 310 and between gate spacers 308, and forming interlayer dielectric 395.

The descriptions of the various embodiments of the disclosure have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A finFET comprising:
a nonlinear channel under a gate, the nonlinear channel comprising a first nonlinear sidewall.

2. The finFET of claim 1, wherein the nonlinear channel comprises a second nonlinear sidewall that opposes the first nonlinear sidewall.

3. The finFET of claim 2, wherein the first nonlinear sidewall is a first curved nonlinear sidewall.

4. The finFET of claim 3, wherein the second nonlinear sidewall is a second curved nonlinear sidewall.

5. The finFET of claim 4, wherein the first curved nonlinear sidewall and the second curved nonlinear sidewall are parallel.

6. The finFET of claim 4, wherein the first curved nonlinear sidewall and the second curved nonlinear sidewall share a same central axis of curvature.

7. The finFET of claim 1, further comprising a source in physical contact with a first end surface of the nonlinear channel and a drain in physical contact with an opposing second end surface of the nonlinear channel.

8. The finFET of claim 7, further comprising a gate spacer around the gate.

9. The finFET of claim 1, wherein a channel length of the nonlinear channel is greater than a gate length of the gate.

10. A finFET comprising:
a first nonlinear channel under a gate;
a second nonlinear channel under the gate;
a source in physical contact with respective end surfaces of the first nonlinear channel and the second nonlinear channel; and
a drain in physical contact with respective opposing end surfaces of the first nonlinear channel and the second nonlinear channel.

11. The finFET of claim 10, wherein the first nonlinear channel comprises a first nonlinear sidewall and a second nonlinear sidewall that opposes the first nonlinear sidewall.

12. The finFET of claim 11, wherein the first nonlinear sidewall is a first curved sidewall and the second nonlinear sidewall is a second curved sidewall.

13. The finFET of claim 12, wherein the second nonlinear channel comprises a third nonlinear sidewall and a fourth nonlinear sidewall that opposes the third nonlinear sidewall.

14. The finFET of claim 13, wherein the third nonlinear sidewall is a third curved sidewall and the fourth nonlinear sidewall is a fourth curved sidewall.

15. The finFET of claim 14, wherein the first curved sidewall and the second curved sidewall are parallel and wherein the third curved sidewall and the fourth curved sidewall are parallel.

16. The finFET of claim 15, wherein the first curved sidewall, the second curved sidewall, the third curved sidewall, and the fourth curved sidewall share a same central axis of curvature.

17. The finFET of claim 16, further comprising a gate spacer around the gate.

18. The finFET of claim 10, wherein a channel length of the first nonlinear channel is greater than a gate length of the gate.

19. The finFET of claim 18, wherein a channel length of the second nonlinear channel is greater than the gate length.

20. A finFET fabrication method comprising:
forming a nonlinear fin over a semiconductor substrate;
forming a sacrificial gate over the nonlinear fin;
forming gate spacers upon respective sidewalls of the sacrificial gate;
forming a source in physical contact with a first end surface of the nonlinear fin;
forming a drain in physical contact with a second end surface of the nonlinear fin;
removing the sacrificial gate between the gate spacers; and
forming a replacement gate between the gate spacers,
wherein the nonlinear fin is a nonlinear channel for the finFET, and wherein a channel length of the nonlinear channel is greater than the replacement gate length.
